(19) United States
(12) Patent Application Publication
(10) Pub. No.: US 2003/0184722 A1
(43) Pub. Date: Oct. 2, 2003

(54) Laser repair system and glass mask used for the same

(76) Inventor: Yukio Kyusho, Tokyo (JP)

Correspondence Address: DICKSTEIN SHAPIRO MORIN & OSHINSKY LLP, 1177 Avenue of the Americas, 41st Floor, New York, NY, 10036-2714, US

(21) Appl. No.: 10/393,291

(22) Filed: Mar. 21, 2003

(30) Foreign Application Priority Data
Mar. 27, 2002 (JP) 88439/2002

(51) Int. Cl. G03B 27/52; G03F 1/00; G03B 27/70; G03B 27/72

(52) U.S. Cl. 355/55; 430/5; 355/71; 355/66

(57) ABSTRACT

To provide an optical-proximity-correction (OPC) mask and a laser repair system using the same, which realize the correction working having a resolution equal to or higher than the resolution of a working optical system.

It is possible to realize the working having a ratio R approx. ½ of the conventional ratio by using the pattern of a Cr film formed on a glass substrate same as a photomask as a mask and moreover using a mask in which an OPC pattern such as a serif is formed on the pattern instead of a variable XY slit mechanism used in a general mask repair system.

Moreover, it is possible to accept defects of various sizes and shapes by mounting a conventional variable XY slit mechanism and a slit mechanism using an OPC mask and switching the mechanisms.

### BACKGROUND OF THE INVENTION

1. Field of the Invention

The present invention relates to a laser repair system for correcting a defect of a photomask used for a pattern exposure process in a semiconductor fabrication equipment or liquid-crystal fabrication equipment and a glass mask applied with optical proximity correction (OPC) used for the same.

2. Description of the Prior Art

A laser mask repair system is a system for correcting a defect produced on a photomask used to print a circuit pattern on a silicon wafer by using a laser. The first patent application is performed by Japanese Patent Laid-Open No. 56-164345 (filing date: May 23, 1980). FIG. 1 shows a typical optical device used for a conventional laser mask repair system. A laser beam 7 passing through a rectangle, continuously adjusted by a slit variable mechanism 20 is reduced and imaged on a photomask by an imaging lens to correct a defect.

A correctable minimum size (diffraction limit) R is shown by the following Rayleigh's expression (1):

R=k₁λ/NA (1)

where λ represents the wavelength of laser light, and NA represents the numerical aparture of an objective lense.

In the above expression, k₁ denotes a coefficient decided by an optical system, which is equal to approx. 0.5 in general. According to the expression (1), it is necessary to decrease a wavelength λ or increase NA or realize both decrease of the wavelength λ and increase of the NA in order to decrease the minimum size R.

The wavelength λ depends on a laser used such as the wavelength 0.351 μm of the third harmonic of an Nd:YLF laser or the wavelength 0.263 μm of the fourth harmonic of the laser. Up to the wavelength 0.211 μm of the fifth harmonic can be used but it is not technically practically used at present yet because of the following reason. The wavelength of the fifth harmonic is present in a wavelength region close to a vacuum ultraviolet region. In this region, it is difficult to design and fabricate a high-performance objective lens having a small aberration. In the case of the laser mask repair system, not only a laser beam for working but also illumination light is condensed on a photomask by an objective lens. However, a severe design is required for an objective lens in order to correct a chromatic aberration caused by the difference between the wavelength of an ultraviolet lamp used as an illumination light source and the wavelength of the fifth harmonic. At present, an optical system having a high resolution can be obtained by using a high-performance objective lens for a system in the wavelength of the third or fourth harmonic compared to the case of designing and fabricating a lens for the fifth harmonic by overwhelming difficulties.

In the case of NA, it is more difficult to design a lens having a higher NA. When designing a lens at a wavelength in an ultraviolet region such as the third or fourth harmonic, the number of usable lens materials is limited. Therefore, a realizable NA is up to approx. 0.80 to 0.85.

As described above, the design of decreasing the wavelength λ or increasing the NA is limited in the expression (1). At present, when a design wavelength is equal to λ=0.351 μm of the third harmonic, NA=0.85 is the limit of the realizable NA value of an objective lens in order to realize an optical system having a coefficient k₁=0.5.

By extremely decreasing (shortening) a depth of focus (DOF) or working distance (WD) of a lens, it may be possible to design an objective lens having an NA of 0.9 to 0.95. However, when the WD is decreased, an expensive photomask may be more easily scratched under work because it contacts with something. Moreover, because the autofocus (AF) performance provided for an objective lens controls working characteristics, if the DOF is greatly decreased, working generally becomes unstable and a low-operability system is realized. As a result, the diffraction limit when using the wavelength 0.351 μm results in R=0.25 μm. When executing actual repair working, it is always observed that a curvature at a radius of approx. 0.25 μm is formed at a corner of a rectangular working shape. In other words, even if using an objective lens having the present highest resolution, when working the lens by setting a slit shape to 0.5-μm square, only a circle having a radius of 0.25 μm can be imaged because corners are not resolved as shown in FIG. 2.

### BRIEF SUMMARY OF THE INVENTION

### OBJECT OF THE INVENTION

The present invention is made to solve the above problems and its object is to realize the working of directly using an available lens to improve a resolution up to a degree equal to or higher than the performance actually obtained from the lens.

### SUMMARY OF THE INVENTION

A laser repair system of the present invention is a laser repair system for correcting a pattern on an object by a light spot at which a laser-passing image of a mask is imaged, comprising a laser, a glass mask to be irradiated with a laser beam of the laser and having at least one pattern considering optical proximity correction (OPC), and an imaging optical system for reducing and imaging a passing image of the mask on a plane, wherein the object set on the imaging plane of the imaging optical system by the imaged light spot.

The glass mask may have a plurality of patterns different from each other in shape or size and may be able to select a pattern to be irradiated with the laser beam out of the patterns.

The glass mask may be set to a mechanism for moving the pattern to be irradiated with the laser beam in the direction vertical to the optical-axis direction so that the glass mask can select the pattern out of the OPC patterns.

An OPC pattern formed on the glass mask may be the serif type or hammerhead type.

The glass mask may be constituted by a binary mask formed by a transparent region and an opaque region or a phase-shift mask.

The phase-shift mask may be either of the halftone type and Levenson type.

The shifter material of the phase-shift mask may use one of such materials as MoSi, Si, ZrSi, Cr, and TiSi or a material based on one of these materials.

The glass mask may be set to a fine-adjustment mechanism having a resolution of M/10 μm or less in the optical-axis direction when assuming the contracting-imaging magnification as 1/M and a fine-movement stage mechanism having a resolution of 10M nm or less in the direction vertical to the optical axis.

The laser repair system may further comprises means for measuring the imaged light spot, wherein the fine-movement stage mechanism constitutes the imaged-light-spot measuring means and a feedback servo system and the position of the imaged point in the optical-axis direction may be automatically controlled by the servo system.

Another laser repair system of the present invention is a laser repair system for correcting a pattern on an object by a light spot at which a laser-passing image of a mask is imaged, comprising a laser, a first mask for irradiating the laser beam, a second mask for irradiating the laser beam, and an imaging optical system for reducing and imaging the passing image of the first mask and the passing image of the second mask on the same plane, wherein the object set on the imaging plane of the imaging optical system is worked by the imaged light spot.

One of the two masks may be a glass mask having at least one pattern considering optical proximity correction (OPC), and the other of them may be a variable slit mechanism which can be changed to an optional slit width in two dimensions.

The glass mask may be an OPC mask provided with a square pattern and a pattern having a serif portion at corners of the square pattern and considering optical proximity correction, the OPC pattern may be formed by two glass masks, and the width of the square pattern can be changed in single-axis direction by mutually sliding the two masks in single-axis direction along the principal plane.

Means for switching an optical path for irradiating the laser beam by selecting either of the first mask and second mask may be included.

The glass mask may have a plurality of patterns different from each other in shape or size and may be able to select a pattern to be irradiated with the laser beam out of the patterns.

The glass mask may be set to a mechanism for moving a pattern to be irradiated with the laser beam in the direction vertical to the optical-axis direction so that the glass mask can select the pattern out of the OPC patterns.

The glass mask may be constituted by a binary mask formed by a transparent region and an opaque region or a phase-shift mask.

The phase-shift mask may be either of the halftone type and Levenson type.

The shifter material of the phase-shift mask may use one of such materials as MoSi, Si, ZrSi, Cr, and TiSi or a material based on one of these materials.

An OPC pattern formed on the glass mask may be the serif type or hammerhead type.

A laser beam for irradiating the slit mechanism may be different from a laser beam for irradiating the glass mask in pulse characteristic.

A laser beam for irradiating the glass mask may be a pulse string having a pulse width of 100 fs to 300 ps and a laser beam for irradiating the slit mechanism may be a pulse string having a pulse width of 10 ps to 500 ps.

The laser beams different from each other in pulse characteristic are laser beams emitted from two different lasers.

A beam expander capable of adjusting a beam divergence angle may be independently set in the optical path between the optical-path switching mechanism and the variable slit mechanism and in the optical path between the optical-path switching mechanism and the glass mask.

It may be possible to select an enlargement ratio different from that of a variable XY slit mechanism for the independent beam expander so that a working shape when using the glass mask becomes optimum.

The glass mask may be set to a fine-adjustment mechanism having a resolution of M/10 μm or less in the optical-axis direction when assuming the reducing-imaging magnification as 1/M and a fine-movement stage mechanism having a resolution of 10M nm or less in the direction vertical to the optical axis.

It may be possible to shift an imaging-working position by a very short distance by moving the glass mask in the axis direction vertical to the optical-axis direction.

The laser repair system may further comprises means for measuring the imaged light spot, wherein the fine-movement stage mechanism constitutes the imaged-light-spot measuring means and feedback serve system and the position of the imaged point in the optical-axis direction may be automatically controlled by the servo system.

The fine-adjustment mechanism and the fine-movement stage mechanism may make a focus position when performing working by the variable slit mechanism coincide with a focus position when performing working by the glass mask.

The two glass masks may be glass masks respectively having at least one pattern considering optical proximity correction (OPC).

The two glass masks may be OPC masks respectively provided with a square pattern and a pattern having a serif portion at corners of the square pattern and considering optical proximity correction, the OPC patterns may be formed by two masks, the width of the square pattern can be changed in single-axis direction by mutually sliding the two masks on which the OPC patterns may be formed in single-axis direction along the principle plane, and the axis may be orthogonal to the first and second glass masks.

The two glass masks may be set to a rotation mechanism in which the two masks rotate together in a mask plane by at least 90°.

Means for branching an optical path for applying the laser beam to the first and second masks and joining means for joining passing images of the two masks may be included.

The first glass mask may have only the square pattern portion of an OPC pattern, and the second glass mask may have only serif portions of OPC patterns located at corners of the square pattern.

When assuming the length of one side of the first square pattern of the first glass mask as 100, one side of the second square of the serif portion of the second glass mask may range between 20 and 40, and the length of the overlapped portion of the first and second squares may form a square by a light spot imaged on the OPC pattern having a ratio of 0 to 20.

The first and second glass masks respectively may have a plurality of patterns different from each other in size and a pattern to be irradiated with the laser beam can be selected out of the patterns.

The two glass masks may be respectively constituted by a binary mask formed by a transparent region and an opaque region or a phase-shift mask.

The phase-shift mask may be either of the halftone type and Levenson type.

The shifter material of the phase-shift mask may use one of such materials as MoSi, Si, ZrSi, Cr, and TiSi or a material based on one of these materials.

Means for switching an optical path for applying the laser beam by selecting either of the first mask and the second mask may be included.

A glass mask of the present invention is a glass mask used for a laser repair system for correcting a pattern on an object by a light spot at which the laser-passing image of a mask is imaged, comprising a square pattern and an OPC pattern having a serif portion at corners of the square pattern and considering optical proximity correction (OPC), wherein the OPC pattern is formed by two glass masks, and the width of the square pattern can be changed in single-axis direction by mutually sliding the two glass masks on which the OPC pattern is formed in single-axis direction along the principal plane.

An OPC pattern formed on the glass mask may be the serif type or hammerhead type.

The glass mask may be constituted by a binary mask formed by a transparent region and an opaque region or a phase-shift mask.

The phase-shift mask may be either of the halftone type or Levenson type.

The shifter material of the phase-shift mask may use one of such materials as MoSi, Si, ZrSi, Cr, and TiSi or a material based on one of these materials.

By using a glass mask of the present invention, it is possible to perform working at a resolution equal to or higher than the resolution limit of a working optical system used for a laser repair system. Because it is possible to equivalently exceed the optical design limit of an objective lens, it is possible that a present laser repair system is compatible with the rule one generation ahead. The present system can also become compatible with it by remodeling of a conventional slit mechanism section. Moreover, the system is a very useful technique from the viewpoint that an equipment can be greatly improved at the minimum cost in a short time.

It is convenient to use a laser repair system of the present invention using conventional variable slit mechanism of the present invention and a laser repair system according to the system using a variable slit mechanism together with an OPC mask, and use a conventional slit mechanism for a large defect and apply the correction method by the OPC mask to a defect close to the minimum slit width because it is possible to correct various defects caused by a present photomask at the same time.

Advantages of the present invention further greatly appear in the correction of a halftone phase-shift mask (HT-PSM) most noticed in the recent photomask technology. This is because an HT mask of MoSi or the like absorbs comparatively less laser beam than a normal Cr binary mask and is not easily influenced by heat when it is worked. Therefore, in the case of imaging-working of the HT mask when using an OPC mask, it is expected that a corner portion has a curvature radius almost half of the case of a Cr mask. When working MoSi, a corner protrudes unless selecting an OPC mask having a small serif. Therefore, it is necessary to select an optimum OPC shape. As described above, because it is possible to select OPC of a different serif shape, it is allowed to select a proper serif shape in accordance with the material of a mask to be corrected. Moreover, it is effective to form an OPC mask by an HT-PSM depending on a wavelength used for a laser repair system and further improve the resolution power at an imaging point.

Furthermore, in the case of the laser working using a glass mask of the present invention, tens of nanometers are requested for a moving accuracy for correction. In the case of a conventional system, an XY stage mounting a defective mask to be worked is slightly moved by a piezo-element. However, because feedback control cannot be performed, controllability is low and it is impossible to accurately move the XY stage. By attaching a linear scale to the fine-movement mechanism of an OPC mask and thereby performing control, it is possible to easily perform an operation with an accuracy of tens of nanometers on a working plane. By using the above mechanism, it is possible to perform automatic working within a hundred-nanometers square. Because working is conventionally manually performed, the working is performed at ununiform pitch and caving depth into a glass substrate is not uniform in many cases. However, by performing automatic working in accordance with accurate pitch feed, it is possible to make a working shape flat.

Moreover, by preparing slit-width changing mechanisms respectively using a single-axis OPC mask of the present invention for two axes in two directions orthogonal to each other, simultaneously dividing the mechanisms into two by a half mirror without switching an optical path, arranging these OPC mask mechanisms, combining the mechanisms by the half mirror again, and then imaging an object, it is possible to form a I shape, L shape, and cross shape. These shapes are useful for correction of a defect of a contact hole.

### BRIEF DESCRIPTION OF THE DRAWINGS

The above and other objects, features and advantages of the present invention will become apparent from the following detailed description when taken with the accompanying drawings in which:

FIG. 1 is an illustration showing a configuration of an imaging-working optical system used for a conventional typical laser repair system;

FIG. 2 is an illustration showing a working shape when imaging and working an object by using a conventional typical laser repair system and a normal slit;

FIG. 3A is an illustration showing a design pattern and FIG. 3B is an illustration showing the shape of an OPC pattern;

FIG. 4 is an illustration showing an improvement effect of a working shape when imaging and working an object by an OPC slit;

FIG. 5 is an illustration showing a parameter for evaluating an OPC mask;

FIG. 6 is an illustration showing a basic configuration of the imaging optical system of a laser repair system of a first embodiment of the present invention using an OPC pattern for a slit;

FIG. 7 is an illustration showing a configuration of the imaging optical system of a laser repair system of a second embodiment of the present invention using a plurality of OPC patterns;

FIG. 8 is an illustration showing details of OPC patterns different from each other in shape shown in FIG. 7;

FIG. 9 is an illustration showing a configuration of the variable XY-slit-width mechanism and OPC-mask switching section of a third embodiment of the present invention;

FIG. 10 is an illustration showing an optical path when selecting the variable XY-slit-width mechanism of the third embodiment of the present invention;

FIG. 11 is an illustration showing an optical path when selecting an OPC mask of the third embodiment of the present invention;

FIG. 12 is an illustration showing a configuration when using an independent beam expander for a variable XY-slit-width mechanism and OPC mask of a fourth embodiment of the present invention;

FIGS. 13A and 13B are illustrations showing a configuration of a single-axis slit-width changing mechanism of a fifth embodiment of the present invention using an OPC mask; FIG. 13A being a perspective view of the mechanism and FIG. 13B being a sectional view of the mechanism;

FIG. 14 is an illustration showing a configuration using a single-axis slit-width changing mechanism of a sixth embodiment of the present invention using an OPC mask in both X and Y directions;

FIG. 15 is an illustration showing a configuration obtained by combining a rotation mechanism with a single-axis slit-width changing mechanism of a seventh embodiment of the present invention using an OPC mask;

FIG. 16 is an illustration showing a configuration using a single-axis slit-width changing mechanism of an eighth embodiment of the present inventing using an OPC mask in both X and Y directions and combined with a half mirror;

FIG. 17 is an illustration showing a configuration for obtaining an OPC-mask effect by selecting the serif portion of an OPC mask of a ninth embodiment of the present invention as an independent pattern and synthesizing it;

FIG. 18 is an illustration showing an optical-system configuration of a tenth embodiment of the present invention capable of observing an OPC pattern;

FIG. 19 is a block diagram of an eleventh embodiment of the present invention, which is a system block diagram for displaying a working position by using the working optical system of the tenth embodiment; and

FIG. 20 is an illustration showing an operation flow of the eleventh embodiment of the present invention.

### DETAILED DESCRIPTION OF THE PREFERRED EMBODIMENTS

To use an available objective lens and achieve an object of realizing the working in which resolution is more improved than the resolution obtained by the lens, it is considered in the case of the present invention to realize the laser working exceeding a resolution limit by applying optical proximity correction (OPC) to a laser repair system.

Optical proximity correction is a phenomenon that a dimensional error occurs in a formed pattern because a state of diffraction or interference is slightly changed when a fine pattern of an exposure wavelength or less is formed in an exposure system such as a stepper and a density difference is produced between surrounding patterns. More specifically, when the interval between a mask pattern of 0.20 μm which is an exposure wavelength or less in a KrF excimer laser exposure system having a wavelength of 0.248 μm and an adjacent pattern is slightly wide, it is possible to form an exposure image at a size equal to a set value of a mask pattern. However, when the interval between a mask pattern and an adjacent pattern is decreased to a certain interval or less, a dimensional error occurs in an exposure pattern and the error value increases.

Therefore, a correction value is previously provided for the original data for the pattern so that a dimensional error does not occur in an exposed pattern. The value is referred to as optical proximity correction (OPC).

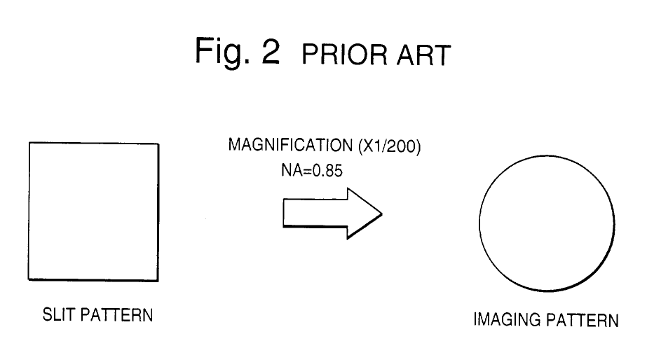

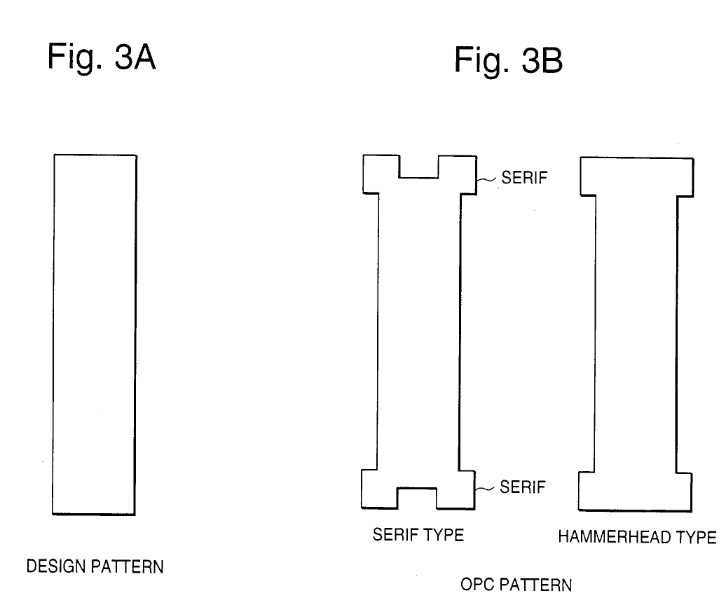

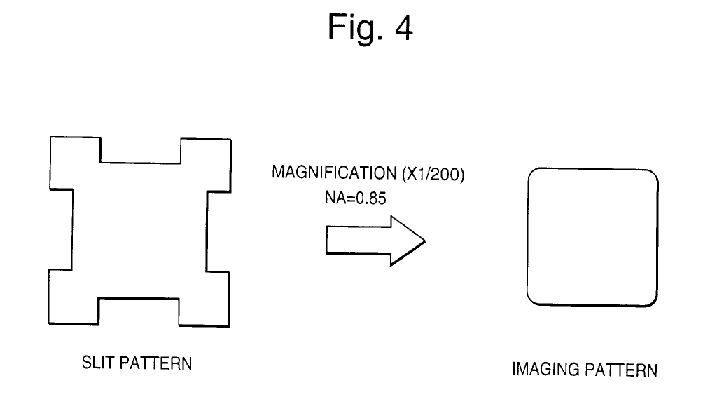

The above principle is applied to a laser mask repair system. When applying patterns (FIG. 3B) referred to as the serif type and hammerhead type which are typical OPC patterns to the slit shape for mask repair corresponding to a working design pattern (FIG. 3A), it is possible to decrease the curvature radius of a corner rounded at a diffraction limit as shown in FIG. 4. In this case, a high-resolution working shape is obtained compared to an imaging-working shape using the conventional slit changing mechanism shown in FIG. 2.

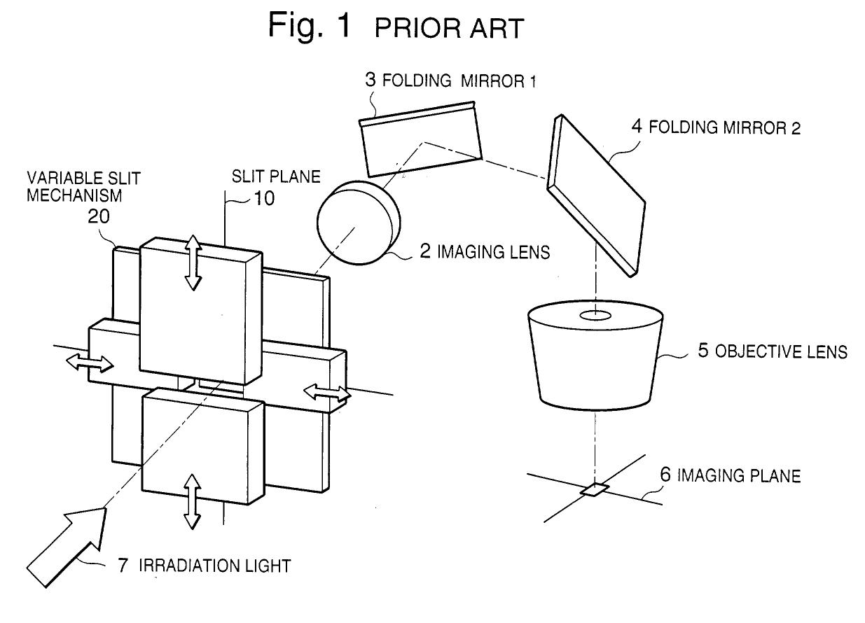

For the present invention, an experiment for confirming the advantage when using an OPC mask is previously performed by using the configuration of the standard optical system of the conventional laser mask repair system shown in FIG. 1. An experiment system is constituted so as to irradiate a variable XY slit 20 with irradiation light 7, guide an image passing through a slit plane 10 to an objective lens 5 by a imaging lens 2, two folding mirrors 3, a folding mirror 4, and contract and image a slit-passing image on an imaging plane 6. The experiment system is a reducing-imaging optical system of ×1/200 which images a slit shape of 100-μm square to a slit shape of 0.5-μm square. The objective lens 5 has an NA of 0.85 and uses a laser beam having a wavelength of 351 nm and a pulse duration of 250 ps. By comparing a result of the laser working when using a normal slit mechanism with the working shape when using an OPC glass mask, the improved state when using the OPC glass mask is examined.

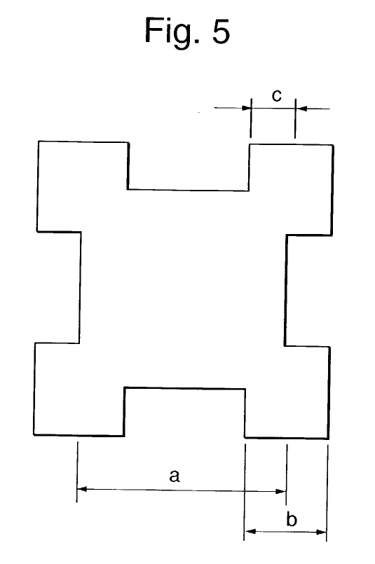

For evaluation of the case of using the OPC mask, the parameter in FIG. 5 is specified. Evaluation is performed by preparing mask patterns shown in FIG. 5 obtained by fixing the dimension a to 100 μm and changing the dimension b to 0, 10, 20, 30, and 40 μm and c to 0, 10, and 20 μm. As a result, a remarkable improvement effect is obtained for b=30-40 μm and c=0 μm. As the value of c increases, the effect of the resolution of the corner shown in FIG. 4 lowers and it is not remarkable when the values of b and c are equal to or less than approx. 30 μm.

Moreover, as a result of performing the evaluation by setting the laser pulse duration to 30 ps, it is clarified that the effect of OPC can be obtained because pulse width becomes approx. 1/10 and thermal diffusion length decreases even if values of b and c are smaller than the above value.

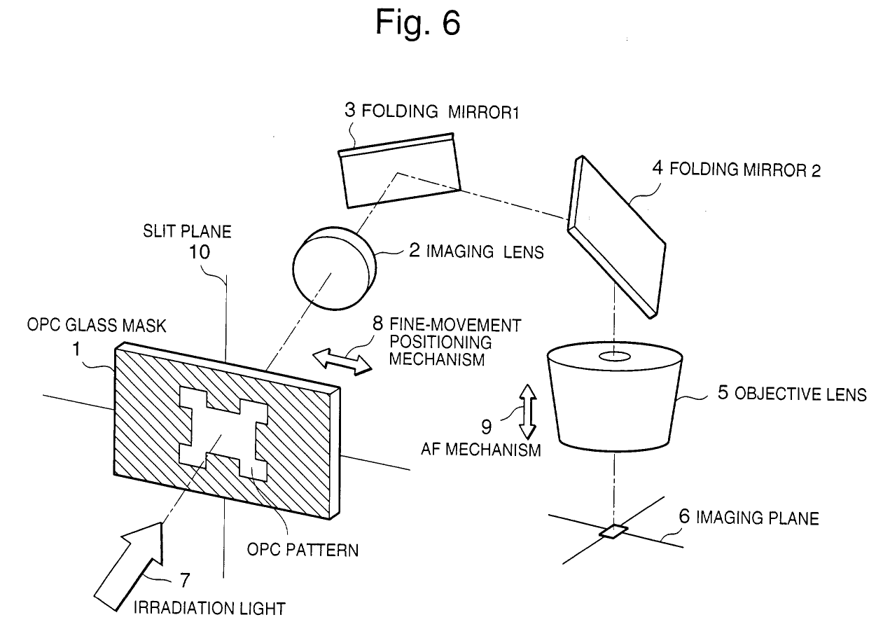

Then, embodiments of a laser mask repair system of the present invention will be described below by referring to the accompanying drawings. FIG. 6 shows a configuration of a first embodiment of the present invention, in which a mask having an OPC pattern is set instead of a variable slit mechanism section 20 of the conventional general laser repair optical system shown in FIG. 1. The collimated irradiation light 7 irradiates an OPC glass mask 1 located on the slit plane 10. A mask-passing image is guided to the objective lens 5 by the imaging lens 2 and two folding mirrors 3, folding mirror 4. The objective lens 5 contracts and images the mask-passing image on the imaging plane 6. The objective lens 5 is provided with an autofocus mechanism (AF mechanism 9) and the OPC glass mask 1 is mounted on a fine-movement positioning mechanism 8. In this case, the OPC pattern uses a square imaged pattern (FIG. 5).

A slit used for a conventional laser mask repair system is not fixed in shape or dimension but it is constituted so that slit widths of X and Y axes are changed in a range of approx. 0 to 10 μm. However, in the case of the configuration of this embodiment in FIG. 6, the OPC mask 1 is formed by forming a pattern of a Cr thin film on a glass substrate like a normal photomask. Because the pattern on the OPC mask is one fixed pattern, it is impossible to correct it so as to adjust it to the size of a defect. That is, the dimension of a mask having an OPC pattern is set to a minimum working dimension and a defect larger than the dimension is corrected and worked by a plurality of shots over the whole of the defect by moving an XY stage on which a defective photomask on the imaging plane 6 is mounted or a fine-movement stage mounted on the XY stage.

When a stage is moved by a very slight distance of approx. 50 nm, there is a method of moving an OPC mask by a very slight distance. The latest working optical system for laser repair normally has a reduction rate of approx. ×1/100 to ×1/200. Therefore, to shift an imaging position by moving an OPC mask, the OPC mask is moved by a distance 100 to 200 times larger than a distance over which the stage is actually moved on a defective mask. To fine-movement-adjust an imaged pattern on a photomask, a configuration of the present invention can be easily controlled and is advantageous to secure a high accuracy. For example, to accurately shift a portion to be worked and corrected by 10 nm, the moving distance of an OPC mask is equal to 2 μm when a reduction rate is ×1/200. Thus, in the case of a movement of micron order, positioning can be made every 50 nm even if using a positioning system using a standard linear scale. Therefore, a level at which there is no problem on control resolution is obtained.

For the above embodiment, a case is described in which an OPC mask uses a binary mask formed by a Cr thin film same as a normal photomask. However, it is possible to use one of various types of phase-shift masks developed for high resolution. For example, it is possible to use a Levenson-type phase-shift mask or halftone-type phase-shift mask.

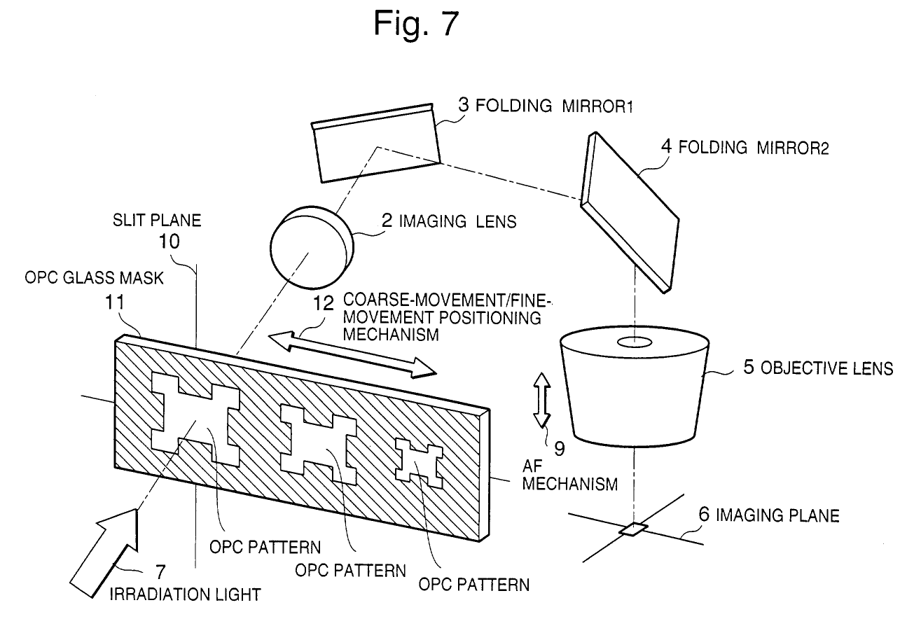

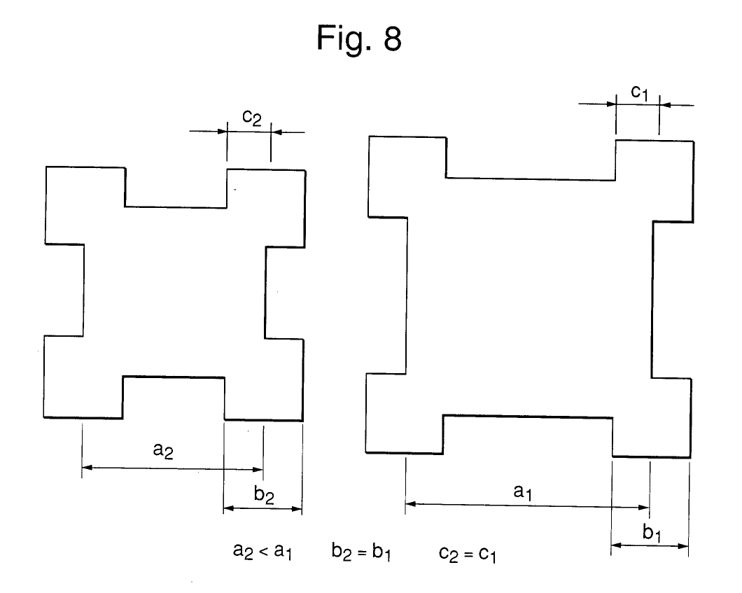

FIG. 7 shows a configuration of a second embodiment. In the case of this embodiment, three OPC patterns different from each other in shape are written in an OPC glass mask 11. As shown in FIG. 8, the patterns used for this embodiment respectively have a serif (b₁=b₂, c₁=c₂) of the same size as that of the OPC pattern shown for the first embodiment to improve the resolution of a corner portion by the same value. This is an example of arranging a plurality of patterns in which only the size (a) of a square pattern is different. Three OPC patterns can be selected in accordance with the size of a defect to be corrected. Moreover, an index mechanism for positioning each OPC pattern and the fine-movement positioning mechanism described for the first embodiment are included. In FIG. 7, two mechanisms are represented by a coarse-movement/fine-movement positioning mechanism 12.

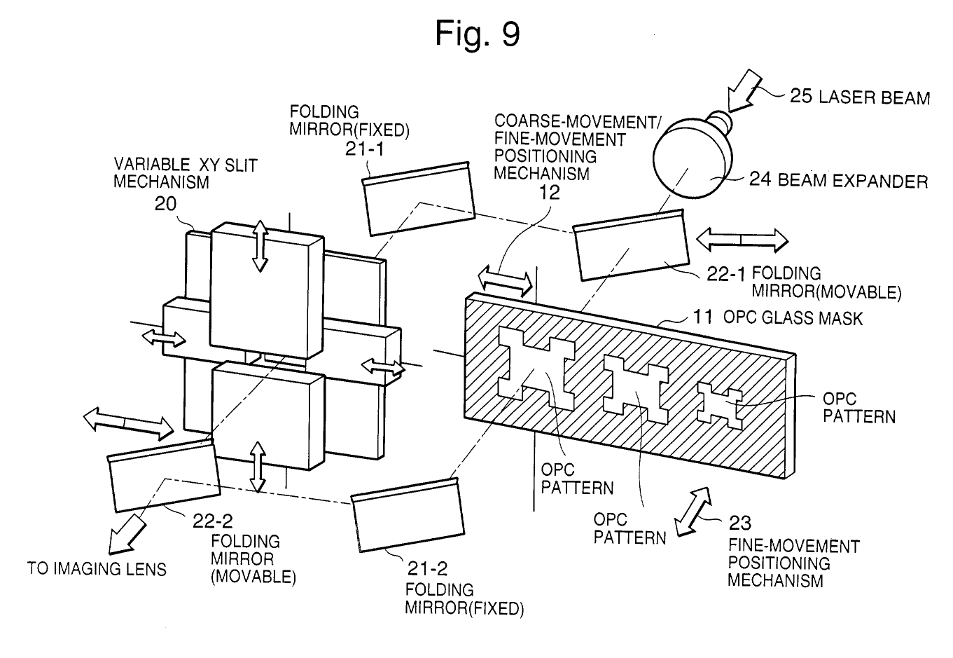

FIG. 9 shows a configuration of a third embodiment. In FIG. 9, the optical path from the imaging lens 2 up to the two folding mirrors, objective lens 5, and imaging plane 6 shown in FIG. 6 has the same configuration as that in FIG. 6. Therefore, these are omitted and represented by the arrow of “to imaging lens”.

This embodiment has a structure of mounting a variable XY slit mechanism 20 used for a conventional typical laser repair system (FIG. 1) and the OPC glass mask 11 (type of having a plurality of OPC patterns) of the second embodiment (FIG. 7) of the present invention, switching the optical path of collimated irradiation light in accordance with the shape or size of a defect to be corrected, and selecting the slit 20 or OPC glass mask 11 as an object to be irradiated. The optical path is switched by simultaneously inserting or extracting two folding mirrors 22-1 and 22-2 shown in FIG. 9 in directions opposite to each other.

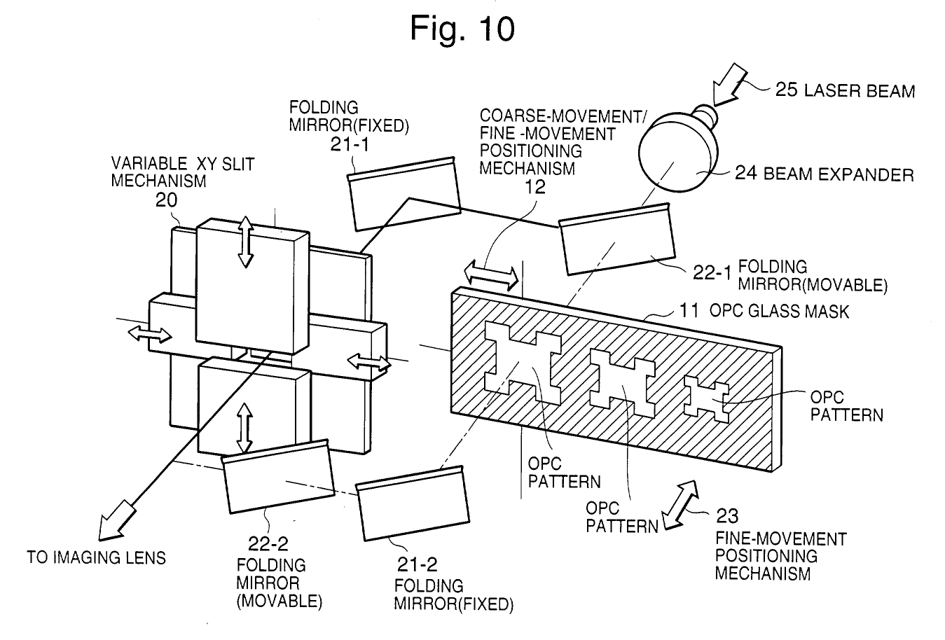

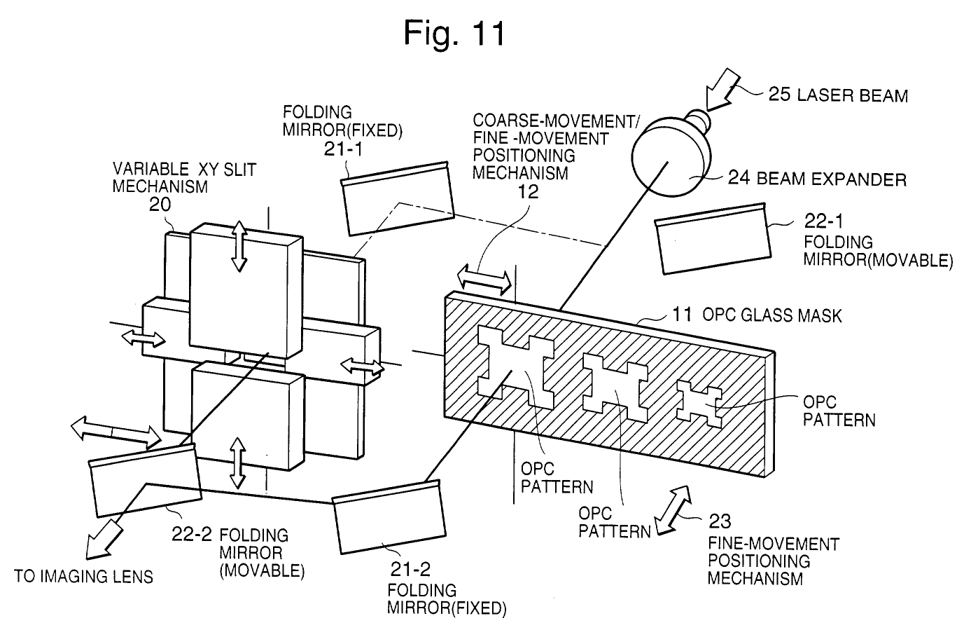

FIG. 10 shows arrangement of movable folding mirrors and an optical path set by the arrangement when selecting the variable XY slit 20 and FIG. 11 shows arrangement of movable folding mirrors and an optical path set by the arrangement when selecting the OPC glass mask 11. An example is shown in which three types of OPC patterns can be selected when selecting the OPC mask. This mechanism is provided with a coarse-movement/fine-movement positioning mechanism 12 same as that of the second embodiment.

In the case of this embodiment, the total optical-path length from a light source up to an imaging point does not depend on beam switching. However, as shown by the schematic view in FIG. 9, when the variable XY slit 20 and OPC glass mask 11 are arranged side by side, the distance from the variable slit 20 up to the objective lens is different from the distance from the OPC mask up to the objective lens. When these distances differ, an imaging position changes. Therefore, either of the focuses is displaced. Even if the focuses can be adjusted by adjusting the objective lens, a problem occurs because magnifications are changed. That is, in the case of this embodiment, it is important to arrange the slit 20 and mask 11 so that the distance up to the lens is not changed by switching the optical path. Actually, the above adjustment is a very severe adjustment. For example, in the case of an imaging-working optical system using an objective lens of NA=0.85, approx. 0.1 μm is requested for an AF (autofocus) accuracy. When considering an imaging-working optical system of ×1/200, an alignment accuracy of a slit (OPC mask) in the optical-axis direction is 20 μm. It is requested to adjust the slit position and OPC mask position in each optical path with this accuracy. Therefore, in the case of this embodiment, a fine-movement positioning mechanism 23 is provided for the mechanism section at the OPC-mask side in the optical-axis direction.

Moreover, for this embodiment, a case is described in which the laser beam to be applied to the variable XY slit 20 is the same as that to be applied to the OPC glass mask 11. However, it is also allowed to separately apply laser pulses different from each other in crest value, pulse duration, or pulse waveform. For example, it is possible to improve an effect by applying a laser beam with a pulse train of 100 fs to 300 ps to an OPC glass mask and a laser beam with a pulse train of 10 ps to 500 ps to a variable XY slit.

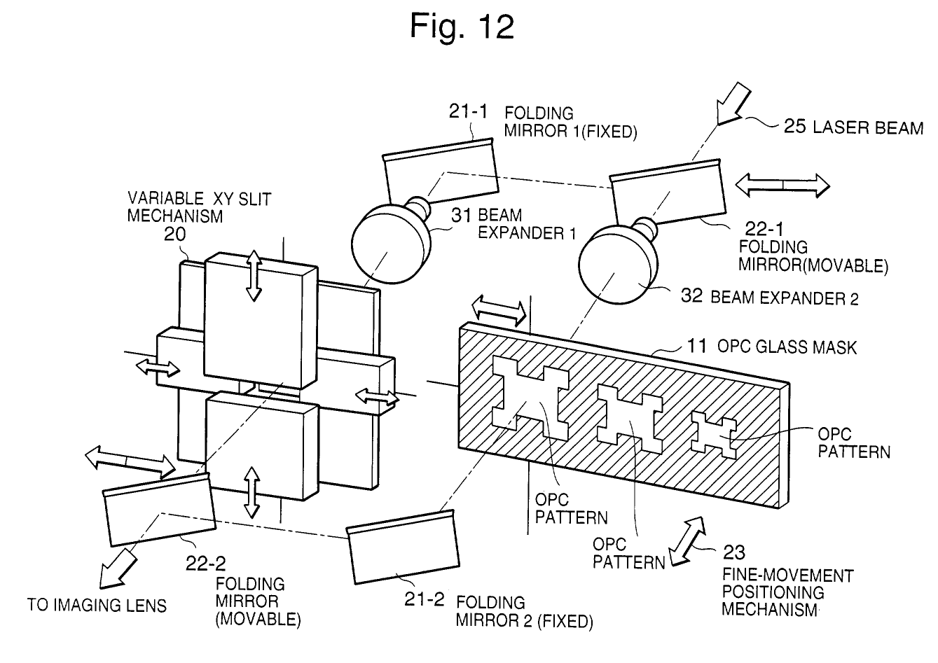

FIG. 12 shows a fourth embodiment. In the case of this embodiment, independent beam expanders 31 and 32 are provided for a variable XY slit 20 and an OPC glass mask 11 respectively while the beam expander described for the third embodiment is shared by the slit and the mask. By making the beam expanders independent of each other, it is possible to change the magnification of only either beam expander or fine-adjust the condition of collimation instead of changing the magnification. Thereby, it is possible to further improve the resolution effect.

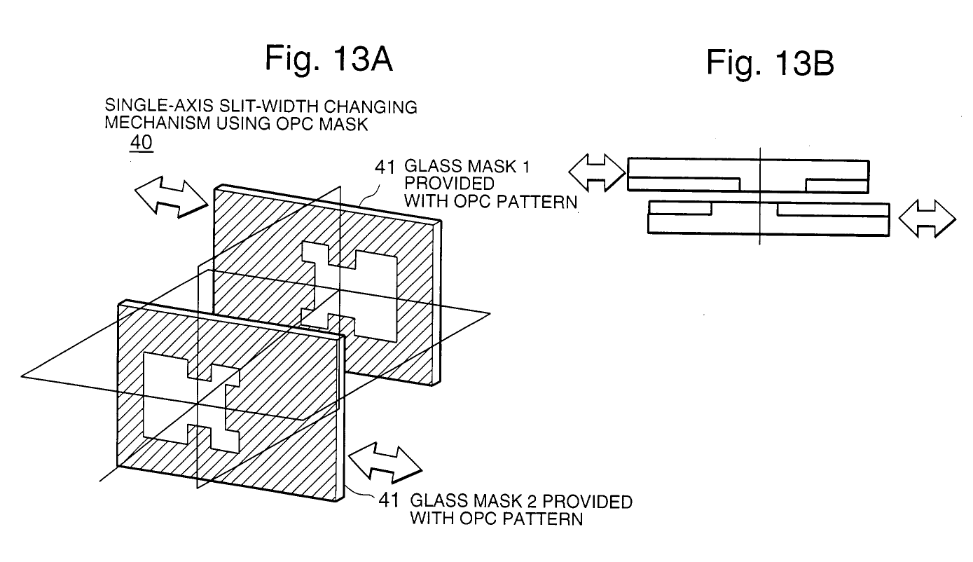

FIGS. 13A and 13B show a fifth embodiment. This embodiment shows an example of constituting a single-axis slit-width changing mechanism 40 using two OPC masks such as a glass mask 41 provided with an OPC pattern and a glass mask 42 provided with an OPC pattern and an OPC mask whose slit width can be changed only in single-axis direction.

FIG. 13 includes FIG. 13A three-dimensionally showing two glass masks by separating them from each other in order to show a positional relation between two OPC patterns and FIG. 13B showing sectional views of the glass masks at the horizontal plane passing through the center of the patterns. As shown by the sectional views of FIG. 13B, glass masks in which two OPC patterns are written are arranged at a minimum interval so that Cr pattern faces are turned inside each other. As previously described, when considering a focus allowance at a working point, approx. 20 μm or less is requested for a pattern gap. Actually, the gap is kept by holding a slippery resin sheet of approx. 5 μm.

By replacing the single-axis slit-width changing mechanism 40 with the OPC glass mask 1 of the laser-repair-system optical system in FIG. 6, it is possible to fine-adjust each glass mask in the right and left directions. Therefore, because a working width can be freely changed though only in single-axis direction, thereby providing a better performance correction.

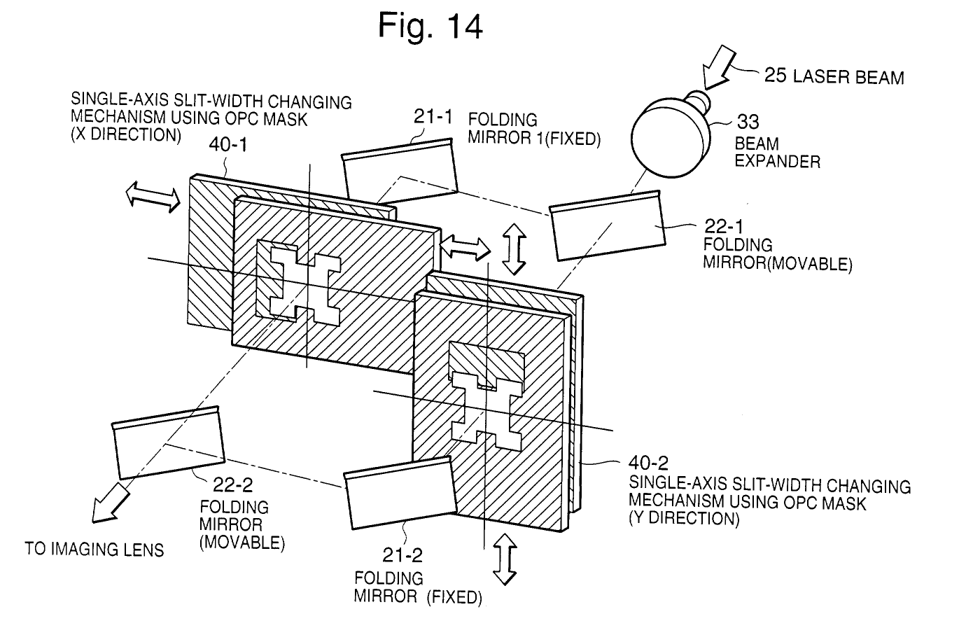

FIG. 14 shows a sixth embodiment in which two single-axis slit-width changing mechanisms 40 respectively using two OPC masks shown in FIG. 13 are used. One of the two mechanisms 40 is a single-axis slit-width changing mechanism 40-1 using an OPC mask pattern whose width can be changed in X direction and the other of them is a single-axis slit-width changing mechanism 40-2 using an OPC mask pattern whose width can be changed in Y direction. A laser beam 25 is applied to either of the two single-axis slit-width changing mechanisms by switching an optical path in accordance with insertion or extraction of folding mirrors 22-1 and 22-2. As an object to be guided to an imaging lens, either of passing images of the single-axis slit-width changing mechanisms using XY OPC mask patterns is selected.

This embodiment shows an example of setting a slit-width adjusting mechanism using the same OPC mask to another axis (orthogonal axis) which cannot be changed for the fifth embodiment (FIG. 13). This embodiment is constituted so as to switch an optical path by movable folding mirrors 22-1 and 22-2, adjust either one-directional slit width, and irradiate an imaging plane. It is possible to select a slit width in accordance with the defect shape of a defective mask to be corrected.

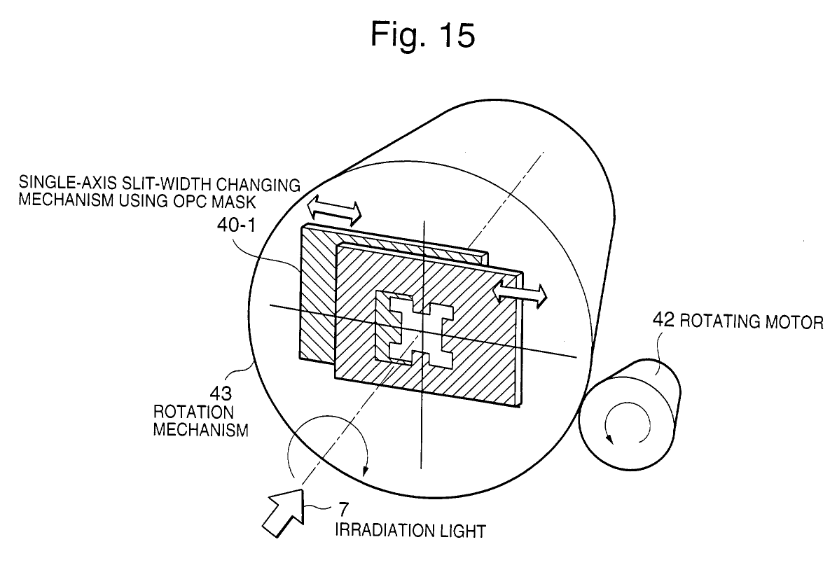

FIG. 15 shows a seventh embodiment. In the case of this embodiment, though an OPC mask adjusting mechanism uses only one axis, it is possible to obtain the same advantages as the sixth embodiment (FIG. 14) because of using a rotation mechanism. The slit-width adjusting mechanism in FIG. 15 is set to the position of the OPC glass mask 1 of the optical system in FIG. 6 or the position of the OPC glass mask 11 of the optical system in FIG. 7 instead of the glass masks 1 and 11.

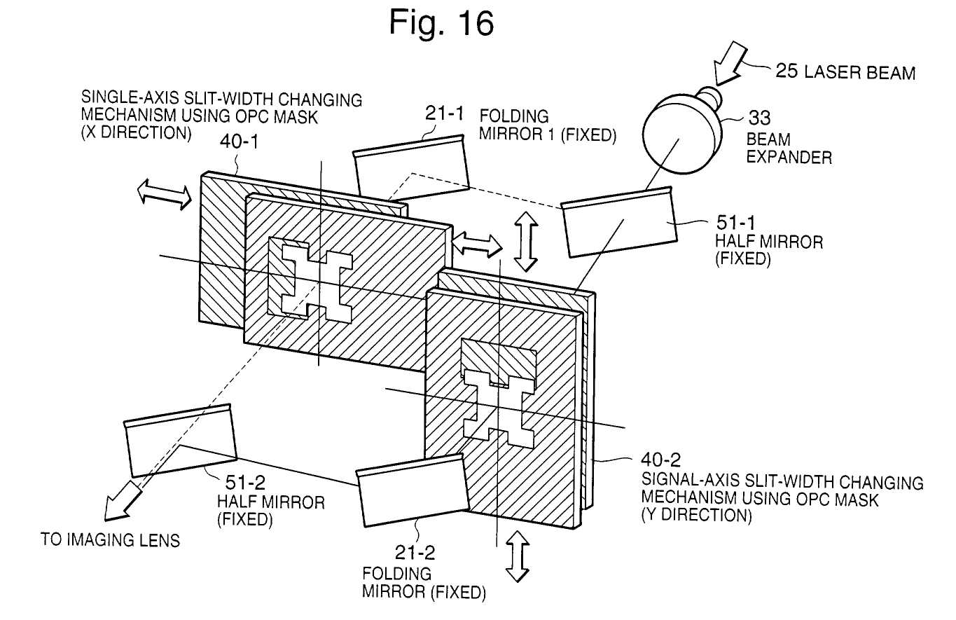

FIG. 16 shows an eighth embodiment. This embodiment uses a configuration obtained by replacing the movable folding mirrors 22-1 and 22-2 in the optical system of the sixth embodiment in FIG. 14 with a fixed half mirror 51, in which the optical axis of collimated light is divided into two by a half mirror 51-1, the single-axis slit-width changing mechanism using an OPC mask pattern shown for the fifth embodiment in FIG. 13 is set so that axes are orthogonal to each other, and finally two beams are combined by a half mirror 51-2 (combination mirror) to image the synthesized beam by an imaging lens.

By using this embodiment, it is possible to form I, L, and cross shapes. Therefore, it is possible to accept a more complex defect shape.

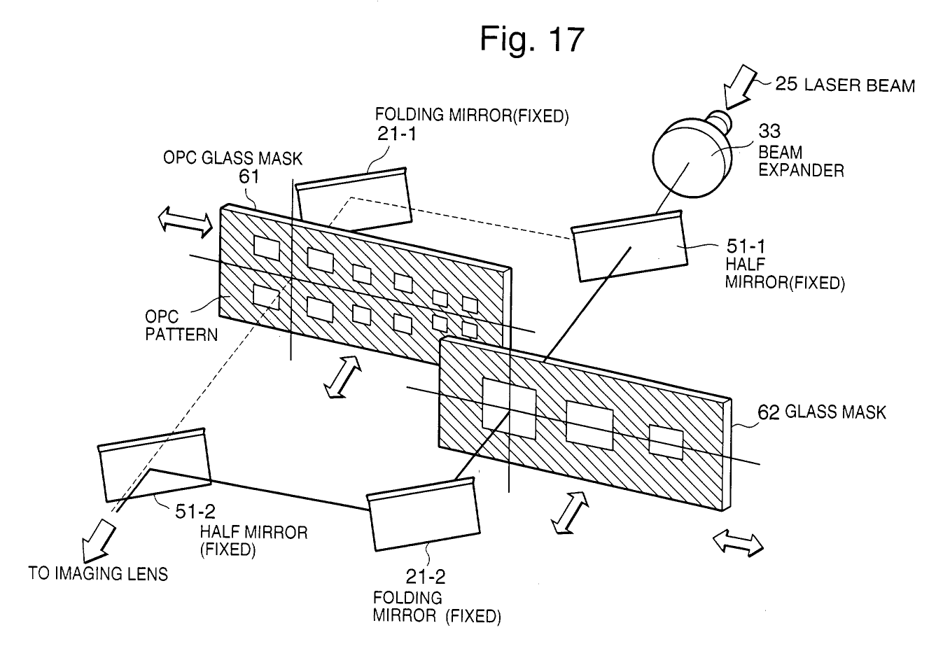

FIG. 17 shows a ninth embodiment. Also this embodiment has a configuration of dividing the optical axis of collimated light into two by a half mirror 51-1, passing the light through a glass mask 62 having a normal slit shape free from OPC and a glass mask 61 independently having the shape of a serif portion for OPC, combining these passing images by a half mirror 51-2 again, and imaging the synthesized beam by an imaging lens, in which the normal slit shape free from OPC and the serif shape respectively have a plurality of patterns so that the shapes can be selected and a combination of them can be changed.

By combining different serif sizes, it is possible to select states in which OPC are different from each other in effectiveness and further increase an acceptable width as in the above embodiment.

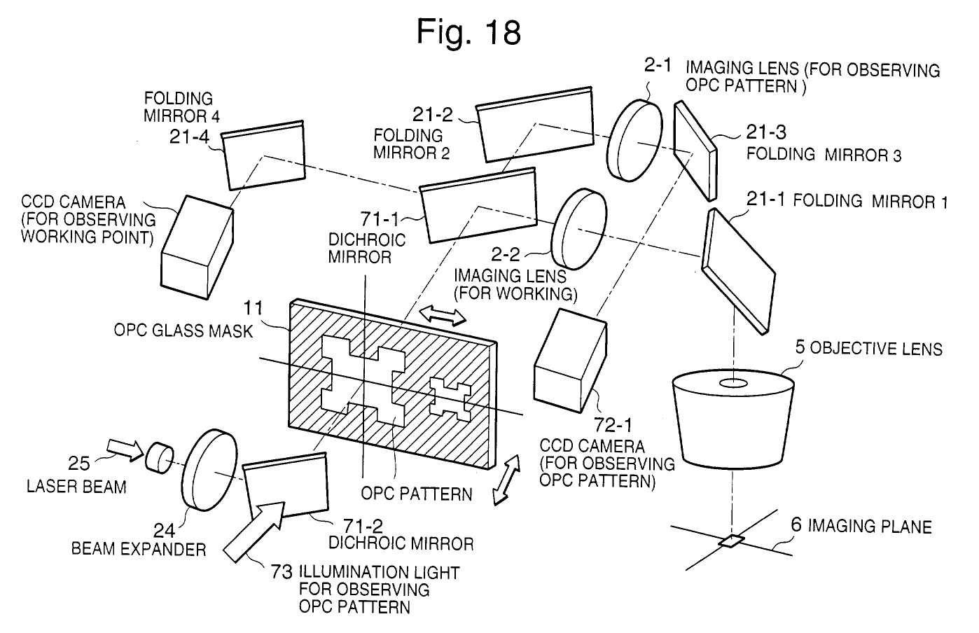

FIG. 18 shows a tenth embodiment of a laser-working optical system. This embodiment shows a specific example of an optical system for accurately showing a position at which an object is actually worked when selecting an OPC mask in the laser repair optical system of the first embodiment of the present invention using OPC mask shown in FIG. 6 or the third embodiment shown in FIG. 9.

The configuration is constituted by a laser-beam optical system for working, an optical system for observing an OPC pattern, and an optical system for observing a working point.

The laser-beam optical system for working is constituted so as to set a dichroic mirror 71-2 (two-wavelength mirror) for reflecting a laser beam 25 and passing illumination light 73 for observing an OPC pattern in an optical path through which the laser beam 25 passes, reflect the laser beam 25, and make the laser beam 25 enter an OPC glass mask 11. The system uses a configuration in which a laser-passing image of the OPC glass mask passes through another dichroic mirror 71-1 having the same wavelength characteristic as 71-2 and is imaged on an imaging plane 6 through a imaging lens 2-2, folding mirror 21-1, and objective lens 5.

The optical system for observing an OPC pattern is constituted so as to make the illumination light 73 enter the dichroic mirror 71-2 and the OPC glass mask 11 from a direction orthogonal to the laser beam 25. The system uses a configuration of using another dichroic mirror 71-1, thereby passing and separating the passing image of the OPC glass mask 11 by a passing image of the wavelength of the illumination light 73 and imaging the passing image on the CCD of a CCD camera 72-1 through the folding mirror 21-2, imaging lens 2-1, and folding mirror 21-3.

Moreover, the optical system for observing a working point uses a configuration of making an image at a working point on the imaging plane 6 pass through the objective lens 5, folding mirror 21-1, imaging lens 2-2, and dichroic mirror 71-1, and imaging the image on the CCD of a CCD camera 72-2 through a folding mirror 21-4.

The above configuration makes it possible to accurately monitor the shape of an OPC pattern and it can be used for confirmation of the position and shape of an OPC mask. Converting the above information into data by an image processor is very useful because it is possible to display a contour to be imaged and worked by an OPC mask in accordance with the data or use the contour as a pilot beam for showing a working region from the next time after once adjusting the contour to the image information showing an actual working shape and position obtained from the working-point-observing optical system.

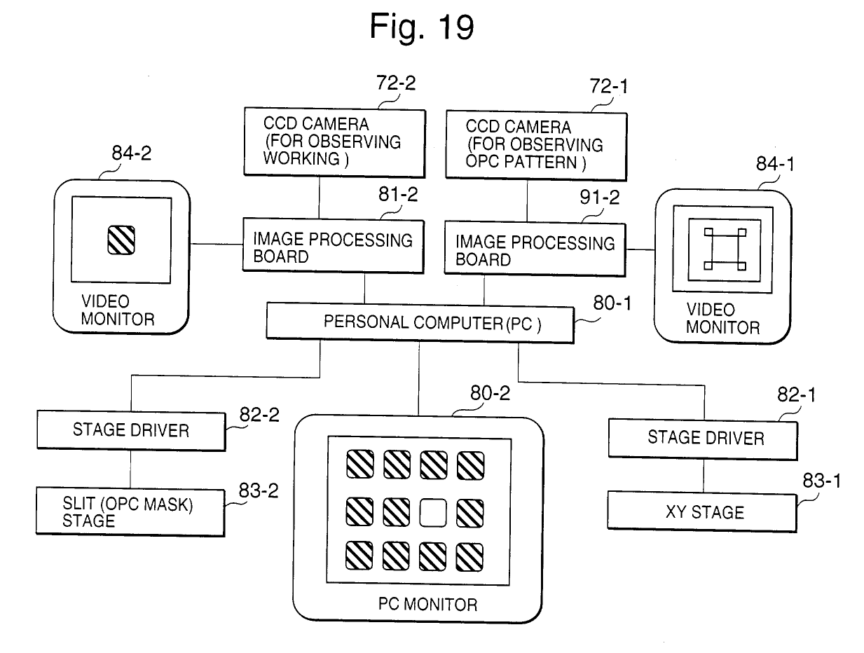

FIG. 19 shows a configuration of an eleventh embodiment of the present invention, which is a system block diagram for displaying a working position by using the working optical system of the tenth embodiment. A personal computer (PC) shown in FIG. 19 analyzes an image 84-1 obtained by directly monitoring an OPC pattern by a CCD camera 72-1 and an image 84-2 obtained by observing an actual working result by a CCD camera 72-2 through image processors 81-1 and 81-2 respectively. Moreover, by adjusting (calibrating) the fine-movement positioning mechanism of the stage 83-2 of an OPC mask through a stage driver 82-2 so that the above data values for the images 84-1 and 84-2 coincide with each other or controlling an XY stage 83-1 on which a defect-correcting mask to be worked is mounted through a stage driver 82-2, it is possible to construct a system capable of displaying a working position.

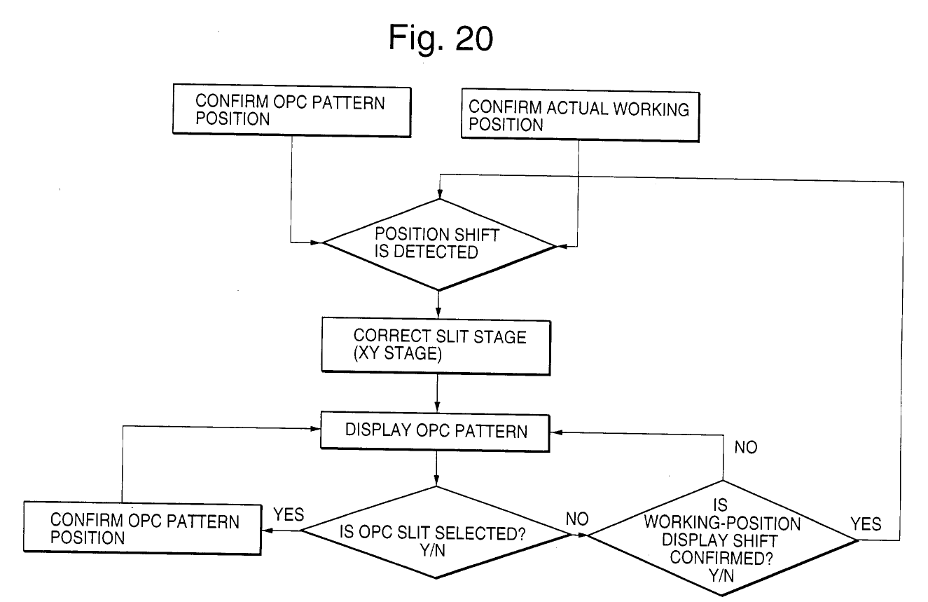

FIG. 20 shows a schematic operation flow of a working position processing at that time.

While the present invention has been described in connection with certain preferred embodiments, it is to be understood that the subject matter encompassed by the present invention is not limited to those specific embodiments. On the contrary, it is intended to include all alternatives, modifications, and equivalents as can be included within he spirit and scope of the following claims.

What is claimed is:

1. A laser repair system for correcting a pattern on an object by a light spot at which a laser-passing image of a mask is imaged, comprising:
a laser;
a glass mask to be irradiated with a laser beam of the laser and having at least one pattern considering optical proximity correction (OPC); and
an imaging optical system for contracting and imaging a passing image of the mask on a plane, wherein
the object set on the imaging plane of the imaging optical system by the imaged light spot.

2. The laser repair system according to claim 1, wherein
the glass mask has a plurality of patterns different from each other in shape or size and is able to select a pattern to be irradiated with the laser beam out of the patterns.

3. The laser repair system according to claim 2, wherein
the glass mask is set to a mechanism for moving the pattern to be irradiated with the laser beam in the direction vertical to the optical-axis direction so that the glass mask can select the pattern out of the OPC patterns.

4. The laser repair system according to claim 2, wherein
an OPC pattern formed on the glass mask is the serif type or hammerhead type.

5. The laser repair system according to claim 1, wherein
the glass mask is constituted by a binary mask formed by a transparent region and an opaque region or a phase-shift mask.

6. The laser repair system according to claim 5, wherein
the phase-shift mask is either of the halftone type and Levenson type.

7. The laser repair system according to claim 6, wherein
the shifter material of the phase-shift mask uses one of such materials as MoSi, Si, ZrSi, Cr, and TiSi or a material based on one of these materials.

8. The laser repair system according to claim 1, wherein
the glass mask is set to a fine-adjustment mechanism having a resolution of M/10 μm or less in the optical-axis direction when assuming the contracting-imaging magnification as 1/M and a fine-movement stage mechanism having a resolution of 10M nm or less in the direction vertical to the optical axis.

9. The laser repair system according to claim 8, further comprising:
means for measuring the imaged light spot; wherein
the fine-movement stage mechanism constitutes the imaged-light-spot measuring means and a feedback servo system and the position of the imaged point in the optical-axis direction is automatically controlled by the servo system.

10. A laser repair system for correcting a pattern on an object by a light spot at which a laser-passing image of a mask is imaged, comprising:
a laser;
a first mask for irradiating the laser beam;
a second mask for irradiating the laser beam; and
an imaging optical system for contracting and imaging the passing image of the first mask and the passing image of the second mask on the same plane, wherein
the object set on the imaging plane of the imaging optical system is worked by the imaged light spot.

11. The laser repair system according to claim 10, wherein
one of the two masks is a glass mask having at least one pattern considering optical proximity correction (OPC), and
the other of them is a variable slit mechanism which can be changed to an optional slit width in two dimensions.

12. The laser repair system according to claim 11, wherein
the glass mask is an OPC mask provided with a square pattern and a pattern having a serif portion at corners of the square pattern and considering optical proximity correction,
the OPC pattern is formed by two glass masks, and
the width of the square pattern can be changed in single-axis direction by mutually sliding the two masks in single-axis direction along the principal plane.

13. The laser repair system according to claim 11, wherein
means for switching an optical path for irradiating the laser beam by selecting either of the first mask and second mask is included.

14. The laser repair system according to claim 11, wherein
the glass mask has a plurality of patterns different from each other in shape or size and is able to select a pattern to be irradiated with the laser beam out of the patterns.

15. The laser repair system according to claim 11, wherein
the glass mask is set to a mechanism for moving a pattern to be irradiated with the laser beam in the direction vertical to the optical-axis direction so that the glass mask can select the pattern out of the OPC patterns.

16. The laser repair system according to claim 11, wherein
the glass mask is constituted by a binary mask formed by a transparent region and an opaque region or a phase-shift mask.

17. The laser repair system according to claim 16, wherein
the phase-shift mask is either of the halftone type and Levenson type.

18. The laser repair system according to claim 16, wherein
the shifter material of the phase-shift mask uses one of such materials as MoSi, Si, ZrSi, Cr, and TiSi or a material based on one of these materials.

19. The laser repair system according to claim 11, wherein
an OPC pattern formed on the glass mask is the serif type or hammerhead type.

20. The laser repair system according to claim 11, wherein
a laser beam for irradiating the slit mechanism is different from a laser beam for irradiating the glass mask in pulse characteristic.

21. The laser repair system according to claim 20, wherein
a laser beam for irradiating the glass mask is a pulse train having a pulse duration of 100 fs to 300 ps and a laser beam for irradiating the slit mechanism is a pulse train having a pulse duration of 10 ps to 500 ps.

22. The laser repair system according to claim 20, wherein
the laser beams different from each other in pulse characteristic are laser beams emitted from two different lasers.

23. The laser repair system according to claim 11, wherein
a beam expander capable of adjusting a beam divergence angle is independently set in the optical path between the optical-path switching mechanism and the variable slit mechanism and in the optical path between the optical-path switching mechanism and the glass mask.

24. The laser repair system according to claim 23, wherein
it is possible to select an enlargement ratio different from that of a variable XY slit mechanism for the independent beam expander so that a working shape when using the glass mask becomes optimum.

25. The laser repair system according to claim 11, wherein
the glass mask is set to a fine-adjustment mechanism having a resolution of M/10 μm or less in the optical-axis direction when assuming the reducing-imaging magnification as 1/M and a fine-movement stage mechanism having a resolution of 10M nm or less in the direction vertical to the optical axis.

26. The laser repair system according to claim 25, wherein
it is possible to shift an imaging-working position by a very short distance by moving the glass mask in the axis direction vertical to the optical-axis direction.

27. The laser repair system according to claim 25, further comprising:
means for measuring the imaged light spot; wherein
the fine-movement stage mechanism constitutes the imaged-light-spot measuring means and feedback serve system and the position of the imaged point in the optical-axis direction is automatically controlled by the servo system.

28. The laser repair system according to claim 25, wherein
the fine-adjustment mechanism and the fine-movement stage mechanism make a focus position when performing working by the variable slit mechanism coincide with a focus position when performing working by the glass mask.

29. The laser repair system according to claim 10, wherein
the two glass masks are glass masks respectively having at least one pattern considering optical proximity correction (OPC).

30. The laser repair system according to claim 29, wherein
the two glass masks are OPC masks respectively provided with a square pattern and a pattern having a serif portion at corners of the square pattern and considering optical proximity correction,
the OPC patterns are formed by two masks,
the width of the square pattern can be changed in single-axis direction by mutually sliding the two masks on which the OPC patterns are formed in single-axis direction along the principle plane, and
the axis is orthogonal to the first and second glass masks.

31. The laser repair system according to claim 30, wherein
the two glass masks are set to a rotation mechanism in which the two masks rotate together in a mask plane by at least 90°.

32. The laser repair system according to claim 29, wherein
means for branching an optical path for applying the laser beam to the first and second masks and joining means for joining passing images of the two masks are included.

33. The laser repair system according to claim 32, wherein
the first glass mask has only the square pattern portion of an OPC pattern, and
the second glass mask has only serif portions of OPC patterns located at corners of the square pattern.

34. The laser repair system according to claim 33, wherein
when assuming the length of one side of the first square pattern of the first glass mask as 100,
one side of the second square of the serif portion of the second glass mask ranges between 20 and 40, and
the length of the overlapped portion of the first and second squares forms a square by a light spot imaged on the OPC pattern having a ratio of 0 to 20.

35. The laser repair system according to claim 33, wherein
the first and second glass masks respectively have a plurality of patterns different from each other in size and a pattern to be irradiated with the laser beam can be selected out of the patterns.

36. The laser repair system according to claim 29, wherein
the two glass masks are respectively constituted by a binary mask formed by a transparent region and an opaque region or a phase-shift mask.

37. The laser repair system according to claim 36, wherein
the phase-shift mask is either of the halftone type and Levenson type.

38. The laser repair system according to claim 36, wherein
the shifter material of the phase-shift mask uses one of such materials as MoSi, Si, ZrSi, Cr, and TiSi or a material based on one of these materials.

39. The laser repair system according to claim 29, wherein
means for switching an optical path for applying the laser beam by selecting either of the first mask and the second mask is included.

40. A glass mask used for a laser repair system for correcting a pattern on an object by a light spot at which the laser-passing image of a mask is imaged, comprising:
a square pattern and an OPC pattern having a serif portion at corners of the square pattern and considering optical proximity correction (OPC), wherein
the OPC pattern is formed by two glass masks, and
the width of the square pattern can be changed in single-axis direction by mutually sliding the two glass masks on which the OPC pattern is formed in single-axis direction along the principal plane.

41. The glass mask according to claim 40, wherein
an OPC pattern formed on the glass mask is the serif type or hammerhead type.

42. The glass mask according to claim 40, wherein
the glass mask is constituted by a binary mask formed by a transparent region and an opaque region or a phase-shift mask.

43. The glass mask according to claim 42, wherein
the phase-shift mask is either of the halftone type or Levenson type.

44. The glass mask according to claim 42, wherein
the shifter material of the phase-shift mask uses one of such materials as MoSi, Si, ZrSi, Cr, and TiSi or a material based on one of these materials.
